(19) United States
(12) Patent Application Publication
(10) Pub. No.: US 2026/0206176 A1
(43) Pub. Date: Jul. 16, 2026

(54) TEMPERATURE CONTROL OF SYSTEMS

(71) Applicant: Aivres Systems Inc., Fremont, CA (US)

(72) Inventor: SHIN-CHI SHEN, New Taipei City (TW)

(21) Appl. No.: 19/635,019

(22) Filed: Mar. 31, 2026

(51) Int. Cl. H05K 7/20

(52) U.S. Cl. CPC H05K 7/20172; H05K 7/20727; H05K 7/20836

(57) ABSTRACT

Methods, systems, and apparatus for temperature control are provided. An example system includes electronic components, a control circuit, one or more fans, and a housing enclosing thereof. The control circuit is configured to receive data representing a first air temperature value at an air inlet of the housing, a power consumption for the system, and a respective fan speed for each of the one or more fans, and determine an airflow volume through the housing based on the respective one or more fan speeds for the one or more fans. The control circuit is further configured to determine a second air temperature value at an air outlet based on the first air temperature value at the air inlet, the power consumption, and the airflow volume. The air outlet is downstream of the air inlet along an air flow path through the housing.

### TECHNICAL FIELD

The present disclosure is related to temperature control of systems.

### BACKGROUND

Electronic devices are widely deployed across numerous technological fields. During operation, many such devices include electrical, electronic, and/or electromechanical components that consume electrical power and consequently generate heat. If the generated heat is not adequately dissipated, elevated temperatures may degrade performance, reduce reliability, or shorten the operational lifetime of the devices.

### SUMMARY

The present disclosure describes systems, devices, circuits, methods, and techniques for temperature control, e.g., managing a temperature at an air outlet of a housing in a system by automatically determining and/or controlling the temperature at the air outlet of the housing without relying on data sensed by a thermal sensor located in a vicinity of the air outlet.

One aspect of the present disclosure features a system, including a housing, a plurality of electronic components, a control circuit, and one or more fans. The housing encloses the plurality of electronic components, the control circuit, and the one or more fans. The control circuit is configured to receive data representing a first air temperature value at an air inlet of the housing, a power consumption for the system, and a respective fan speed for each of the one or more fans, determine an airflow volume through the housing based on respective one or more fan speeds for the one or more fans, and determine a second air temperature value at an air outlet based on the first air temperature value at the air inlet, the power consumption, and the airflow volume. The air outlet is downstream of the air inlet along an air flow path through the housing.

In some implementations, the control circuit may be configured to: for each of the one or more fans, determine the airflow volume through the housing based on the respective fan speed for the fan and a one-to-one mapping between fan speeds configurable for the fan and corresponding airflow volumes for the fan.

The one-to-one mapping may be determined for each of the one or more fans by operations including: for each of the fan speeds configurable for the fan, measuring an airflow volume through the housing generated by the fan in a wind tunnel, and determining the one-to-one mapping for the fan by interpolating the fan speeds configurable for the fan and the measured airflow volumes for the fan speeds.

The control circuit may be further configured to determine a temperature difference between the second air temperature value at the air outlet and the first air temperature value at the air inlet, and determine the second air temperature value at the air outlet based on the temperature difference and the first air temperature value at the air inlet.

The temperature difference may be determined according to an expression as: ΔT=k×P/V, where ΔT represents the temperature difference, k represents a predetermined coefficient, P represents the power consumption, and V represents the airflow volume.

The control circuit may also be configured to determine whether the second air temperature value satisfies a threshold temperature value, and update at least one of the one or more respective fan speeds for the one or more fans in response to determining that the second air temperature value fails to satisfy the threshold temperature value.

The control circuit may be further configured to: for each of the one or more fans, determine a candidate fan speed for the fan based on the second air temperature value at the air outlet; and select, as an updated fan speed for the fan, a fan speed from (i) the candidate fan speed and (ii) additional fan speeds for the fan based on sensor data associated with one or more electronic components of the plurality of electronic components in the system.

In some implementations, the control circuit may be configured to: receive one or more updated fan speeds for the one or m ore fans, determine an updated airflow volume through the housing based on the one or more updated fan speeds for the one or more fans, and determine an updated second air temperature value at the air outlet based on the updated airflow volume.

The control circuit may be configured to determine the second air temperature value at the air outlet without relying on data sensed by a thermal sensor located in a vicinity of the air outlet. The control circuit may also be configured to receive data representing the power consumption for the system from a power supply unit of the system. The control circuit may further be configured to receive data representing the first air temperature value at the air inlet of the housing from a thermal sensor located in a vicinity of the air inlet. In some implementations, the control circuit may include a Baseboard Management Controller (BMC).

Another aspect of the present disclosure features a method wherein the control circuit comprises a Baseboard Management Controller (BMC). The method includes: receiving data representing a first air temperature value at an air inlet of the housing, a power consumption for the system, and a respective fan speed for each of the one or more fans, determining an airflow volume through the housing based on respective one or more fan speeds for the one or more fans, and determine a second air temperature value at an air outlet based on the first air temperature value at the air inlet, the power consumption, and the airflow volume, the air outlet being downstream the air inlet along an air flow path through the housing.

The method may further include determining, for each of the one or more fans, the airflow volume through the housing based on the respective fan speed for the fan and a one-to-one mapping between fan speeds configurable for the fan and corresponding airflow volumes for the fan.

The one-to-one mapping may be determined for each of the one or more fans by operations comprising: for each of the fan speeds configurable for the fan, measuring an airflow volume through the housing generated by the fan in a wind tunnel, and determining the one-to-one mapping for the fan by interpolating the fan speeds configurable for the fan and the measured airflow volumes for the fan speeds.

The method may further include determining a temperature difference between the second air temperature value at the air outlet and the first air temperature value at the air inlet, and determining the second air temperature value at the air outlet based on the temperature difference and the first air temperature value at the air inlet.

The temperature difference may be determined according to an expression as: ΔT=k×P/V, where ΔT represents the temperature difference, k represents a predetermined coefficient, P represents the power consumption, and V represents the airflow volume.

The method may also include determining whether the second air temperature value satisfies a threshold temperature value, and updating at least one of the one or more respective fan speeds for the one or more fans in response to determining that the second air temperature value fails to satisfy the threshold temperature value.

In some implementations, the method may include: for each of the one or more fans, determining a candidate fan speed for the fan based on the second air temperature value at the air outlet, and selecting, as an updated fan speed for the fan, a fan speed from (i) the candidate fan speed and (ii) additional fan speeds for the fan based on sensor data associated with one or more electronic components of the plurality of electronic components in the system.

Another aspect of the present disclosure features one or more non-transitory computer-readable storage media storing instructions that, when executed by one or more computers, cause the one or more computers to perform respective operations similar to those described above with respect to the method.

Another aspect of the present disclosure features an apparatus, including at least one processor, and one or more non-transitory computer-readable media storing instructions executable by the at least one processor to perform operations. The operations include: receiving data representing a first air temperature value at an air inlet of a housing of a system, a power consumption for the system, and a respective fan speed for each of one or more fans of the system, wherein the housing encloses a plurality of electronic components of the system and the one or more fans, determining an airflow volume through the housing based on respective one or more fan speeds for the one or more fans; and determining a second air temperature value at an air outlet based on the first air temperature value at the air inlet, the power consumption, and the airflow volume, the air outlet being downstream the air inlet along an air flow path through the housing.

The details of one or more implementations of the subject matter of this specification are set forth in the Detailed Description, the Claims, and the accompanying drawings. Other features, aspects, and advantages of the subject matter will become apparent to those of ordinary skill in the art from the Detailed Description, the Claims, and the accompanying drawings.

### DESCRIPTION OF DRAWINGS

FIG. 1A is a schematic diagram of an example of a system having multiple electronic components, a control circuit, and a cooling module.

FIG. 1B is a schematic diagram of an example of a control circuit of a system configured to control a cooling module in the system.

FIG. 2A is a schematic diagram of air flow paths across one or more housings of one or more systems.

FIG. 2B is a schematic diagram of an example computing device and an air flow path associated with the example computing device.

FIG. 3 illustrates a first table that represents a mapping between fan operating speeds and corresponding airflow volumes, and a second table that represents candidate fan speeds for multiple fans associated with different groups of electronic components within a system.

FIG. 4 is a flow diagram of an example process of managing a temperature at an air outlet of a system.

FIG. 5 illustrates an example computing device.

FIG. 6 illustrates an example computing system.

Like reference numbers and designations in the various drawings indicate like elements.

### DETAILED DESCRIPTION

A system such as a computing system configured for high-performance workloads—such as training or executing artificial intelligence (AI) models—may include one or more central processing units (CPUs), graphical processing units (GPUs), tensor processing units (TPUs), field-programmable gate arrays (FPGAs), or other hardware accelerators that generate substantial heat during operation. To maintain suitable operating temperatures of the system, various thermal management techniques may be employed. For example, the system may incorporate one or more cooling modules configured to dissipate heat generated by internal components. Such cooling modules may include air-cooling devices (e.g., fans, heat sinks, or airflow channels), liquid-cooling devices (e.g., cold plates, coolant circulation systems, or immersion cooling systems), or combinations thereof.

In some implementations, one or more thermal sensors may be positioned in situ within the system, such as in the vicinity of heat-generating electronic components and/or near inlet or outlet regions of a system enclosure, housing, or packaging. Measurements obtained from such thermal sensors may provide real-time tracking of temperature conditions within the system, enabling control systems to dynamically adjust operating parameters of one or more cooling modules or other system components to maintain desired thermal conditions.

Implementation of the present disclosure provide systems, devices, circuits, methods, and techniques for managing (e.g., determining and controlling) a temperature at an air outlet of a system, e.g., automatically without relying on data sensed by a thermal sensor positioned at or near the air outlet. In some implementations, the disclosed techniques enable estimation of the temperature at the air outlet based on specific operating conditions of the system, thereby enabling thermal controls that do not require direct temperature measurement at the air outlet.

In some implementations, a system may include a housing that encloses multiple electronic devices, a cooling module configured to remove/dissipate heat generated by the multiple electronic devices, and a control circuit configured to regulate operations of the cooling module based on temperature measurements and other operating parameters. The system may include a variety of electronic or electromechanical systems that generate heat during operation, such as computing systems, networking equipment, storage systems, telecommunications equipment, industrial control systems, or other electronic devices. Examples of such systems may include computing systems, data processing systems, networking equipment, storage systems, industrial equipment, consumer electronics, and other systems incorporating heat-generating components. In many implementations, these systems can include devices such as printed circuit boards (PCBs) populated with integrated circuits, power electronics, memory devices, sensors, and other components that may produce significant thermal loads during operation. In the context of a computing system/device, the electronic components may include various processors such as central processing units (CPUs), graphics processing units (GPUs), tensor processing units (TPUs), field-programmable gate arrays (FPGAs), memory modules, power management circuits, and other integrated circuits mounted on printed circuit boards (PCBs). The cooling module may include air-cooling mechanisms, liquid-cooling mechanisms, or combinations thereof.

Electronic components generate heat during operation due to electrical power consumption. The amount of heat generated may depend on operating conditions such as computational workload, clock frequency, voltage levels, and/or utilization of various processing resources. The generated heat may increase the temperature of the surrounding air and structural components within the system housing. Elevated temperatures may adversely affect the performance, reliability, and operational lifespan of electronic components and system hardware. For example, excessive heat may accelerate component degradation, increase leakage currents in semiconductor devices, reduce processing performance due to thermal throttling, increase system power consumption, and potentially cause system instability or failure.

To mitigate these effects, systems may employ thermal management systems configured to dissipate heat from electronic components. Such thermal management systems may include one or more cooling modules. In some implementations, the cooling module may include air-cooling components such as fans, blowers, heat sinks, airflow ducts, or ventilation channels configured to circulate air through the system housing. In other implementations, the cooling module may include liquid-cooling components such as pumps, coolant circulation loops, cold plates, heat exchangers, coolant distribution units (CDUs), or fluid conduits configured to transfer heat away from electronic components. These cooling mechanisms may be mounted on or near PCBs, compute nodes, trays, or other structural elements of the system to facilitate heat dissipation.

For ease of explanation, the following description primarily refers to implementations in which the system is, for example, a computing system including one or more computing devices. For example, the system may include a server or data processing system having one or more compute trays, blades, or nodes arranged within a chassis. Each tray or node may include multiple processors (e.g., CPUs or GPUs), memory modules, and associated circuitry mounted on one or more PCBs. The housing of the system may define one or more airflow paths extending from an air inlet region to an air outlet region, allowing air to circulate through the housing to remove heat generated by the internal components. In some implementations, one or more fans may be positioned at various locations within the housing to draw air from the inlet toward the outlet. Although the following examples primarily refer to an air-cooling setup, the described techniques may also be applied to systems employing other cooling mechanisms or hybrid cooling architectures.

In some implementations, a thermal sensor may be positioned near the air outlet of the system to measure the outlet air temperature in situ. The measured outlet temperature may be used by a control circuit to regulate the operation of one or more cooling devices, such as adjusting fan speeds to maintain the outlet temperature within a desired range. In some cases, direct measurement of outlet temperature using such sensors may not provide an accurate representation of the overall outlet air temperature. For example, the thermal sensor may be physically mounted on a PCB or other structural component and therefore may measure a localized temperature rather than the bulk/overall temperature of the air exiting the air outlet. In addition, airflow variations, sensor placement constraints, and thermal gradients within the outlet region may further reduce measurement accuracy. As a result, reliance on a single point-based outlet temperature measurement may lead to suboptimal or inefficient thermal control.

Implementations of the present disclosure provide systems and techniques that can address the above-noted limitations of various techniques. For example, the techniques described herein can determine the temperature at the air outlet without relying on data sensed by a thermal sensor positioned in the vicinity of the outlet. Instead, the system may estimate the outlet air temperature based on other measurable operating parameters of the system. In some implementations, the control circuit may determine the outlet temperature using an analytical model or algorithm that considers parameters including the temperature of air entering the system at the air inlet, the power consumption or heat generation rate of electronic components enclosed by the housing, and the airflow volume or mass flow rate through the system (e.g., at the air outlet). For example, the control circuit may determine a temperature difference between the inlet air and the outlet air based on the heat generated by internal components and the airflow characteristics. The outlet air temperature may then be computed by combining the measured inlet air temperature with the calculated temperature difference. Based on the estimated outlet temperature, the control circuit may dynamically adjust operating parameters of the cooling module, such as fan speeds or airflow distribution, to maintain appropriate thermal conditions within the system.

Implementations of the present disclosure can realize one or more of the following technical advantages, effects, and/or benefits. For example, by estimating the outlet temperature using system-level operating parameters rather than relying on data sensed by a dedicated outlet temperature sensor, the disclosed techniques can reduce dependency on sensor placement and improve the accuracy of outlet temperature estimation across varying airflow conditions. In addition, eliminating the need for an outlet-mounted sensor may simplify system design, reduce hardware costs, and avoid potential reliability issues associated with sensor installation or wiring near airflow paths.

In some implementations, the described techniques may also enable more responsive and efficient thermal control. Because the estimation model may incorporate real-time measurements of inlet temperature, power consumption of electronic components, and airflow characteristics, the control circuit may more accurately reflect the dynamic thermal behavior of the system. This improved estimation capability may allow the cooling module to adjust operating parameters proactively, thereby maintaining target thermal conditions while reducing unnecessary cooling effort. As a result, systems implementing the described techniques may achieve improved thermal management efficiency, enhanced reliability of electronic components, and reduced overall power consumption.

“Electronic components” described herein can include, but are not limited to, devices or modules configured to perform computing, storage, communication, or power management functions within a system (e.g., computing device). Such electronic components may be designed to process data, manage memory operations, regulate power distribution, or facilitate input/output operations. Examples of the electronic components can include one or more central processing units (CPUs), one or more graphics processing units (GPUs), or one or more memory units (e.g., dynamic random-access memory (DRAM), static random-access memory (SRAM), non-volatile memory devices such as NVMe drives, or other memory modules). Additional examples include storage devices (e.g., solid-state drives or hard disk drives), network interface controllers (NICs), field-programmable gate arrays (FPGAs), application-specific integrated circuits (ASICs), power management modules, input/output (I/O) controllers, voltage regulators, and accelerators for artificial intelligence or machine learning tasks. For simplicity, the terms “electronic components” and “components” may be used interchangeably to broadly refer to any of those modules described above, integrated within or coupled to a computing device.

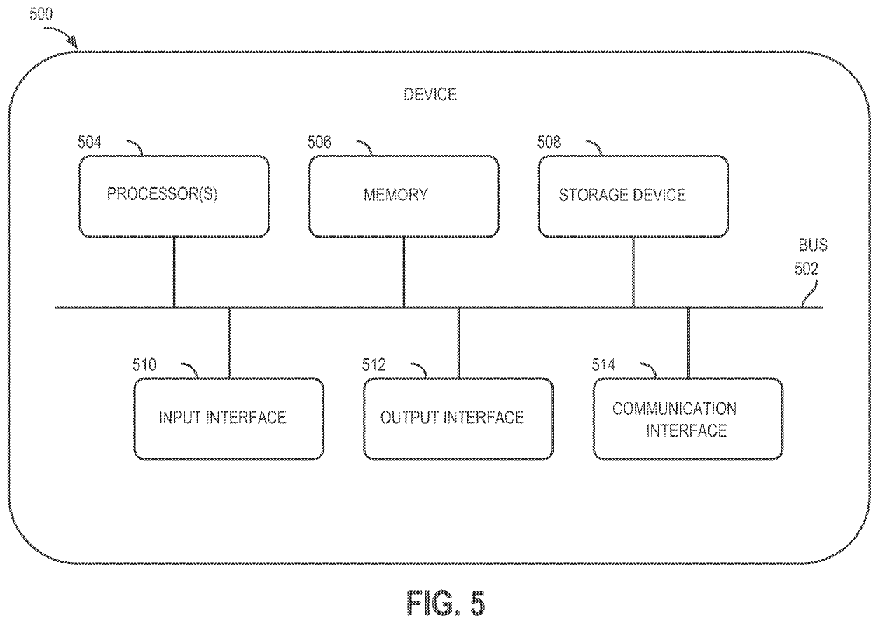

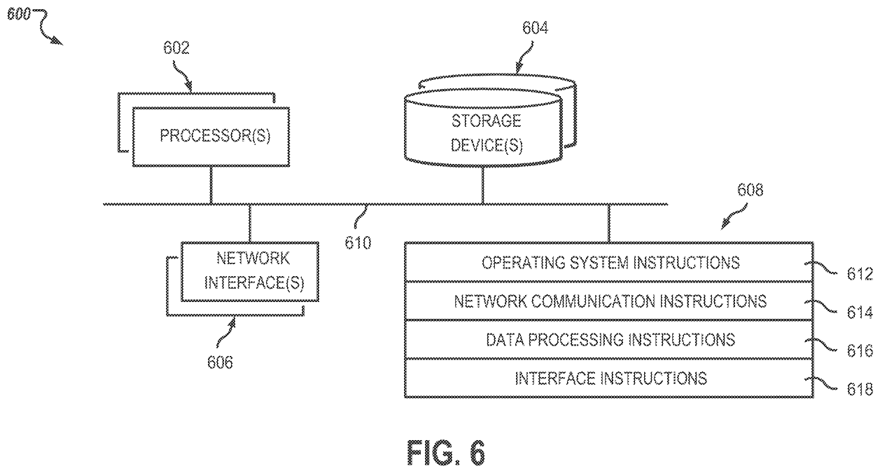

“Computing device(s)” described herein can include one or more computing devices or user devices, such as a server, a personal computer, a laptop, a cellphone, a smart watch, a smart ring, etc. The computing system can further include one or more computing units or nodes on a server, or one or more servers coupled to one another via wired or wireless communication. More details of the computing device are described below in connection with FIG. 5, and more details of the computing system are described below in connection with FIG. 6.

The described subject matters can be implemented using a computer-implemented method; a non-transitory, computer-readable medium storing computer-readable instructions to perform the computer-implemented method; and a computer-implemented system including one or more computer memory devices interoperably coupled with one or more computers and having tangible, non-transitory, machine-readable media storing instructions that, when executed by the one or more computers, perform the computer-implemented method/the computer-readable instructions stored on the non-transitory, computer-readable medium.

The following detailed description is presented to enable any person skilled in the art to make and use the disclosed subject matter in the context of one or more particular implementations. Various modifications, alterations, and permutations of the disclosed implementations can be made and will be readily apparent to those of ordinary skill in the art, and the general principles defined can be applied to other implementations and applications, without departing from the scope of the present disclosure. In some instances, one or more technical details that are unnecessary to obtain an understanding of the described subject matter and that are within the skill of one of ordinary skill in the art may be omitted so as not to obscure one or more described implementations. The present disclosure is not intended to be limited to the described or illustrated implementations, but to be accorded the widest scope consistent with the described principles and features.

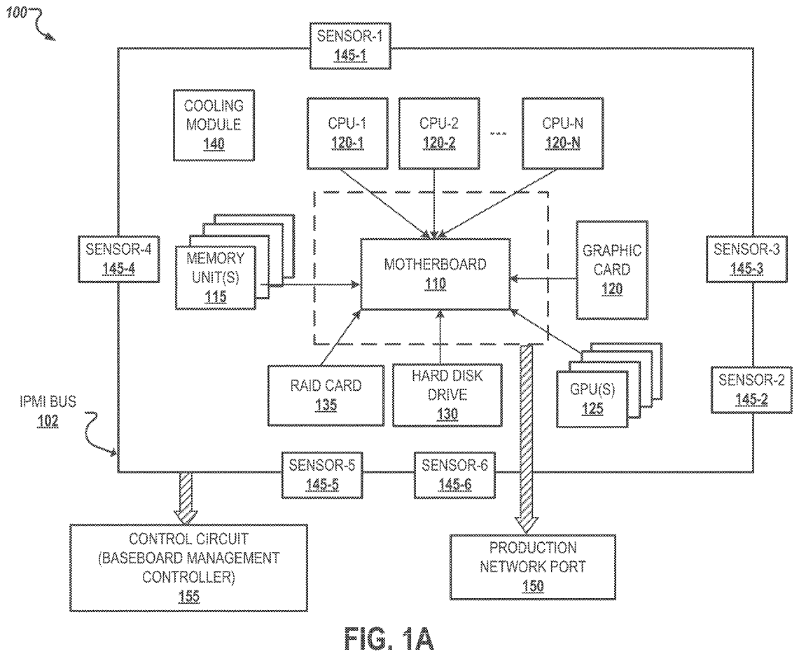

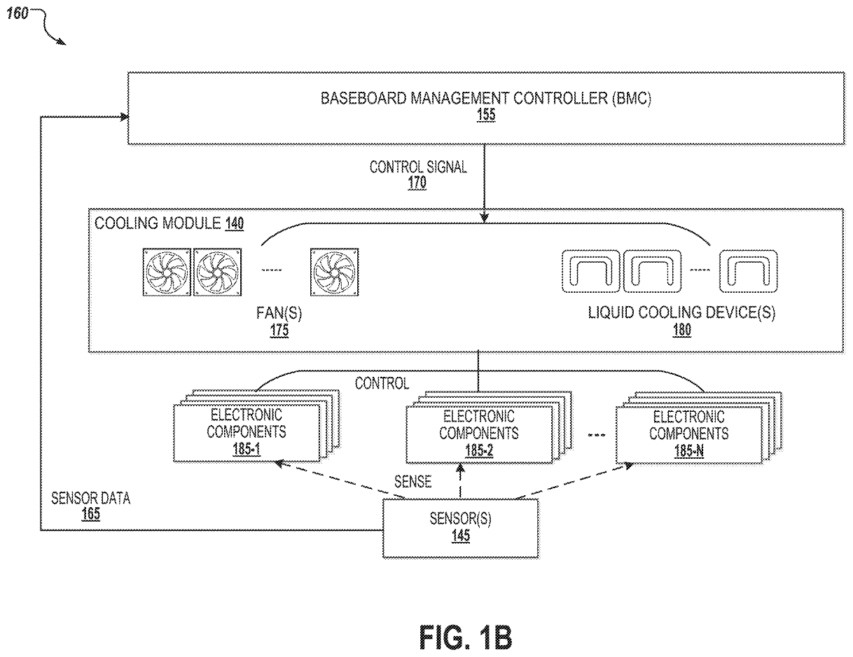

FIG. 1A is a schematic diagram of an example of a system 100 having multiple electronic components, a cooling module 140, and a control circuit 155 configured to manage thermal conditions within the system 100. The system 100 may represent any electronic or electromechanical system that includes heat-generating components. In the example illustrated in FIG. 1A, the system 100 is implemented as a computing system, such as a server or data processing device configured to perform computational workloads. Although the illustrated example relates to a server architecture, the temperature-control techniques described herein may also be applied to other types of systems including computing devices, networking devices, storage systems, telecommunications equipment, industrial control systems, or other suitable electronic devices containing heat-generating components.

The system 100 includes a motherboard 110 configured to support and interconnect various electronic components of the system. The motherboard 110 may include one or more printed circuit boards (PCBs) that provide electrical interconnections, communication pathways, and power distribution for components installed on or connected to the motherboard 110. In some implementations, the motherboard 110 may include communication buses, sockets, connectors, and other circuitry that enable electronic components to exchange data and control signals. Many of these electronic components generate heat during operation due to electrical power consumption, and therefore, appropriate thermal management is desirable to maintain system performance and reliability.

The system 100 may include one or more processing devices configured to perform computational operations. For example, the system 100 may include one or more central processing units (CPUs) and one or more graphics processing units (GPUs). As illustrated in FIG. 1A, the system 100 may include CPUs such as CPU-1 (120-1), CPU-2 (120-2), . . . , CPU-N (120-N), as well as one or more GPUs 125. These processors may be installed in processor sockets or mounted on the motherboard 110 and may communicate with other system components through communication buses such as system buses, high-speed interconnects, or peripheral interconnect interfaces. The CPUs may execute general-purpose instructions associated with operating systems, application software, and control processes, while GPUs or other accelerators may perform parallel computations such as graphics rendering, machine learning inference or training, scientific computing, or other high-performance computing tasks. Note that the number and arrangement of CPUs and GPUs illustrated in FIG. 1A are provided for purposes of illustration and are not intended to be limiting.

The system 100 may further include one or more memory units 115 communicatively coupled to the motherboard 110. The memory units 115 may store instructions, program code, intermediate computational results, and other data used by the processors during operation. In some implementations, the memory units 115 may be connected to the motherboard 110 through memory sockets or memory channels and may communicate with the processors through memory controllers integrated within the CPUs or other system controllers. Examples of memory units may include dynamic random access memory (DRAM), double data rate (DDR) memory modules (e.g., DDR4 or DDR5), high-bandwidth memory (HBM), graphics memory (e.g., GDDR), non-volatile memory modules, or other suitable types of semiconductor memory devices.

In some implementations, the system 100 may also include a redundant array of independent disks (RAID) controller card 135. The RAID card 135 may be installed in an expansion slot of the motherboard 110, such as a PCI Express (PCIe) slot, and may communicate with other system components via the motherboard communication bus. The RAID card may manage multiple storage devices to provide data redundancy, improved storage performance, or both. For example, the RAID card 135 may implement RAID configurations such as RAID 0, RAID 1, RAID 5, RAID 6, or RAID 10. The RAID card 135 may further include processing logic and memory buffers that coordinate read and write operations between the processors and one or more storage devices.

The system 100 may further include one or more storage devices such as a hard disk drive 130. The hard disk drive 130 may be communicatively coupled to the motherboard 110 directly or through a storage controller such as the RAID card 135. The hard disk drive may store persistent data such as operating system files, application programs, configuration data, or user data. In some implementations, the storage device may include magnetic hard disk drives, solid-state drives (SSDs), non-volatile memory express (NVMe) storage devices, or other suitable forms of persistent storage.

The system 100 may additionally include a graphics card 120 configured to perform graphics processing and other parallel computations. The graphics card may be installed in an expansion slot of the motherboard 110, such as a PCIe slot, and may include a graphics processor, dedicated graphics memory, and associated circuitry. In some implementations, the graphics card may support applications including graphics rendering, video processing, scientific computing, and machine learning workloads. Although FIG. 1A illustrates the graphics card as a separate expansion device, in other implementations the graphics processing capabilities may be integrated into one or more GPUs 125 or other processing devices.

To manage the thermal conditions of the electronic components described above, the system 100 may include a cooling module 140. The cooling module 140 may provide air cooling, liquid cooling, or a combination thereof. For example, the cooling module may include fans, blowers, heat sinks, airflow channels, pumps, cold plates, heat exchangers, coolant circulation loops, or other heat-dissipation mechanisms configured to remove heat from the electronic components. The system 100 may also include one or more sensors (e.g., thermal sensors) 145-1, 145-2, 145-3, 145-4, 145-5, and 145-6 (referred to generally as sensors 145 and individually as sensor 145) positioned in the vicinity of respective electronic components. For example, sensor 145-1 may monitor temperatures associated with CPUs 120-1 through 120-N, sensor 145-2 may monitor GPUs 125, sensor 145-3 may monitor the graphics card 120, sensor 145-4 may monitor memory units 115, sensor 145-5 may monitor the RAID card 135, and sensor 145-6 may monitor the hard disk drive 130. In some implementations, these sensors 145-1 to 145-6 may communicate with one another and with other system components via an Intelligent Platform Management Interface (IPMI) bus 102. The IPMI bus 102 may provide a management communication channel that allows system sensors, controllers, and monitoring modules to exchange system health information such as temperature, power consumption, fan status, and other operational parameters. Through the IPMI bus 102, sensor data collected by sensors 145-1 through 145-6 may be provided to the control circuit 155. The control circuit 155 may process the sensor data and control the operation of the cooling module 140, such as adjusting fan speeds or pump operation, to regulate temperatures of the electronic components and maintain desired ambient conditions within the system. The control circuit 155, in some implementations, can include a baseboard management controller (BMC).

The system 100 may further include a production network port 150 that enables the system 100 to communicate with external networks or other computing devices or systems. The production network port 150 may be communicatively coupled to the motherboard 110 through a network interface controller (NIC) or other networking circuitry. In some implementations, the production network port 150 may support communication protocols such as Ethernet and may include connectors such as RJ-45 ports, optical transceiver modules, or high-speed network adapters. For example, the production network port may support network interfaces including 1-gigabit Ethernet (1 GbE), 10-gigabit Ethernet (10 GbE), 25-gigabit Ethernet (25 GbE), 40-gigabit Ethernet (40 GbE), 100-gigabit Ethernet (100 GbE), or other suitable high-speed networking technologies. Through the production network port, the system 100 may exchange data with external systems, data centers, or cloud infrastructure while executing computational workloads.

FIG. 1B is a schematic diagram of an example of a control circuit 155 of a system 160 configured to control a cooling module 140 in the system 160. The system 160 described here can be the same as, or similar to, the system 100 of FIG. 1A. The system 160 can be a computing system or a computing device. The cooling module 140 can be the same as the cooling module 140 of FIG. 1A. The control circuit 155 can be the same control circuit 155 of FIG. 1A, which can include a baseboard management controller (BMC), as described above. The BMC 155 may be configured to monitor operational conditions of the system 160 and regulate temperatures of various electronic components by controlling operations of the cooling module 140. In particular, the BMC 155 may receive sensor data 165 from one or more sensors 145 (e.g., the sensors 145 of FIG. 1A) distributed throughout the system 160 and may determine appropriate control actions for the cooling module 140 based on the received sensor data.

In some implementations, electronic components within the system 160 may be logically grouped into multiple sets according to characteristics such as device type, thermal behavior, power consumption, and/or physical location within the system housing. Grouping electronic components in this manner may facilitate more effective thermal monitoring and control. For example, a first group of electronic components 185-1 may include one or more CPUs, such as CPUs 120-1 through 120-N shown in FIG. 1A. A second group of electronic components 185-2 may include one or more GPUs, such as GPUs 125 of FIG. 1A. Additional groups may include other components, such as memory devices (e.g., memory units 115 of FIG. 1A), storage controllers, networking devices, or other integrated circuits mounted on the motherboard (e.g., motherboard 110).

Different groups of electronic components may exhibit different thermal characteristics during operation. For example, certain components, such as GPUs, may generate larger amounts of heat under high computational loads, while other components, such as memory modules, may produce lower but more distributed heat. Accordingly, the cooling module 140 may include multiple cooling devices, each arranged to address the cooling requirements of a respective group of electronic components. In implementations employing air cooling, the cooling module 140 may include one or more fans 175 configured to generate airflow through the housing of the system 160. For example, one or more fans may be positioned near an air inlet (or air outlet) of the housing to drive airflow through the housing along an airflow path from the inlet to the outlet. Additional fans may be positioned in the vicinity of particular component groups—such as in front of, behind, below, or above the corresponding electronic components—to enhance localized airflow and improve heat dissipation.

Note that the electronic components described herein are not required to be physically separated or partitioned into distinct regions within the system housing. In some implementations, different groups of electronic components may be distributed across the motherboard or other structural elements of the system without dedicated physical barriers or compartments between them. Accordingly, airflow generated by the cooling module may circulate across multiple groups of electronic components within the shared interior space of the housing.

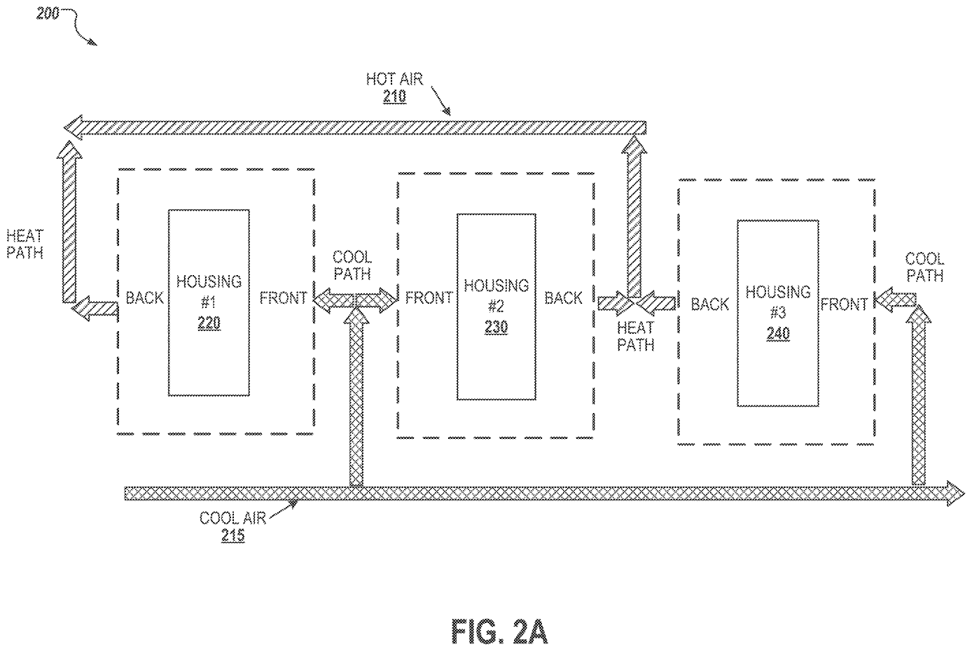

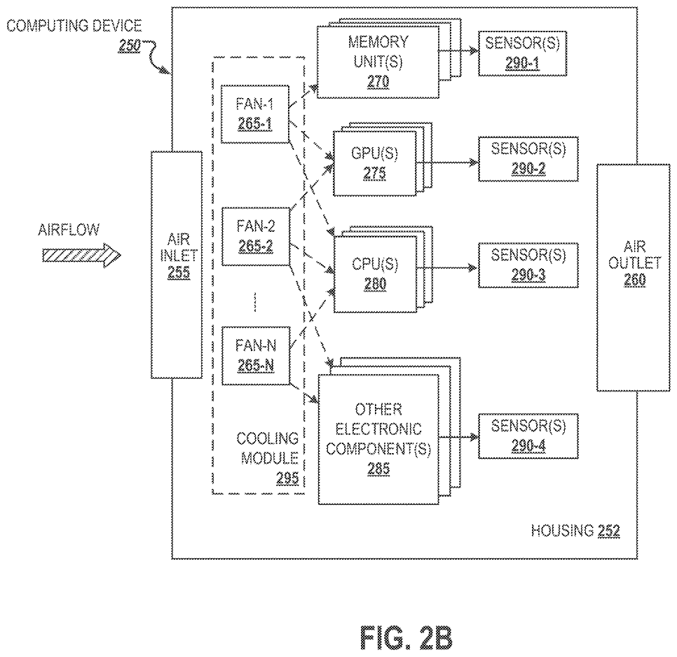

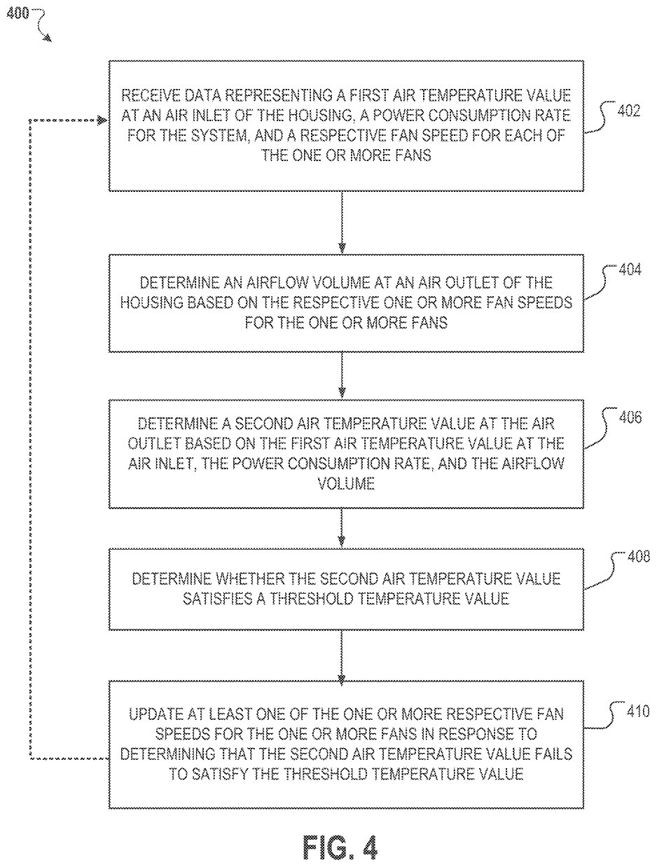

In some implementations, the system 160 may also receive airflow from an external cooling module located outside the system housing, as shown with further details in FIGS. 2B and 4. The external cooling module may include one or more air-moving devices, such as fans or blowers, configured to drive airflow across one or more computing devices or system housings. For example, the external cooling module may be positioned in a rack-level or room-level cooling infrastructure and may direct airflow toward the air inlet of the housing of system 160. The driven airflow may pass through the interior of the housing along an airflow path extending from the air inlet to the air outlet, thereby assisting in removing heat generated by the electronic components within the system. In some implementations, the BMC 155 or another control system may coordinate operations of the internal cooling module 140 with the external cooling module to improve overall thermal management efficiency.

In some implementations, the cooling module 140 may additionally include liquid-cooling components 180 configured to remove heat from selected electronic components. For example, the liquid-cooling components may include cold plates, coolant circulation pumps, coolant distribution units (CDUs), fluid conduits, or heat exchangers, as described above. Thermal sensors positioned near coolant inlet and outlet points may measure coolant temperatures to determine the amount of heat removed by the liquid-cooling system. Although the following description primarily illustrates implementations using air cooling via fans, the techniques described herein may also be applied to systems employing liquid cooling or hybrid cooling configurations, provided appropriate sensor measurements and thermal calculations are available.

The sensors 145 deployed in the described techniques may include temperature sensors configured to measure localized or point temperatures at various locations within the system. These temperature measurements may be transmitted to the BMC 155 for processing. In addition to temperature sensors, the system 160 may include other types of sensors communicatively coupled to the BMC 155. For example, the system 160 may include humidity sensors, air pressure sensors, airflow sensors, liquid pressure sensors, liquid flow sensors, fan tachometers, vibration sensors, current sensors, voltage sensors, acoustic sensors, and/or other sensors configured to measure environmental or operational parameters associated with the system. Data collected from these sensors may provide additional information that can assist the BMC 155 in determining appropriate thermal control actions.

In some implementations, the system 160 may enclosure or package that contains multiple electronic components within a housing. The housing may define an airflow path extending between an air inlet and an air outlet. In some implementations, the system 160 may include multiple computing packages or trays, such as a server chassis containing stacked compute nodes, blades, or trays, each containing processors, memory modules, and associated circuitry. Each tray or node may include a respective BMC configured to manage thermal conditions within that particular enclosure. In some implementations, the system 160 may further include a central management controller or central BMC that coordinates cooling operations across multiple trays or enclosures. For example, a central BMC may control an external cooling module to provide airflow across multiple housings by directing air through respective inlet openings and toward corresponding outlet openings of the housings.

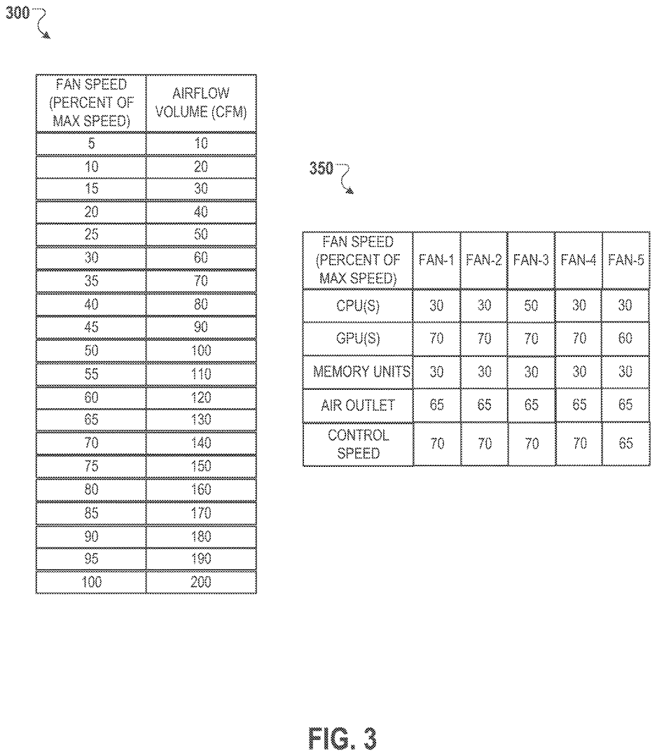

During operation, the BMC 155 may receive sensor data 165 indicating temperature values at various locations within the system housing, including temperatures measured near electronic components and temperatures associated with air entering the housing at the air inlet. Based on this information, the BMC 155 may determine or estimate a temperature value corresponding to the air outlet of the housing. The BMC may then determine appropriate control actions for the cooling module 140 based on the estimated outlet temperature. For example, in implementations using air cooling, the BMC may adjust operating parameters of one or more fans to maintain the outlet air temperature within a desired range. Notably, the outlet temperature determination described herein may be performed without requiring temperature measurements from a sensor physically located at the air outlet. Additional details regarding outlet temperature estimation and associated control algorithms are described below with reference to FIGS. 3 and 4.

Control actions performed by the BMC 155 to regulate air cooling may include coordinated operation of one or more fans 175 within the cooling module 140. For example, the BMC 155 may control the pulse width modulation (PWM) duty cycle supplied to one or more fans, where the PWM duty cycle may range between 0% and 100% to regulate fan speed. In other implementations, the BMC 155 may specify target rotational speeds for the fans, such as target revolutions per minute (RPM) values. The BMC 155 may dynamically adjust these fan operating parameters based on sensor measurements, estimated temperature values, airflow volumes through the packaging or housing, system power consumptions, or other operational factors to maintain desired temperature conditions within the system.

FIG. 2A is a schematic diagram of air flow paths across one or more housings of a system 200. The system 200 can be same as or similar to the system 100 of FIG. 1A or the system 160 of FIG. 1B. As described above, the system 200 can include multiple trays or packages of nodes, each tray or package having a respective housing. As shown in FIG. 2A, the system 200 can include three housings, e.g., housing #1 (220), housing #2 (230), and housing #3 (240), arranged within a larger enclosure, rack, or space for the system 200. Each housing may contain one or more electronic components such as processors (CPUs and/or GPUs), memory devices, and other circuitry that generate heat during operation.

As shown in FIG. 2A and as described above, cooling air 215 may be supplied by an external cooling module and driven through an airflow channel located below the housings. The external cooling module may include one or more fans, blowers, or other air-moving devices configured to generate airflow that travels through the system environment. Portions of the cooling air 215 may, along the cool path, enter respective housings 220, 230, and 240 through air inlet regions located at or near the front side of the housings. The cooling air 215 may then circulate through the interior of each housing 225 along respective air paths defined by respective housings 220, 230, and 240 to remove heat generated by electronic components located therein.

As the cooling air 215 absorbs heat from the electronic components, the temperature of the air increases, forming heated airflow that exits the housings through air outlet regions located at or near the back sides of the housings 220, 230, and 240. The heated air may then travel along a heat path toward an upper airflow region of the system, forming hot air 210 that is removed from the vicinity of the housings 220, 230, and 240. In this manner, airflow may travel from lower regions of the system 200 toward upper regions, while also moving from the front side toward the back side of each housing.

In some implementations, multiple housings 220, 230, and 240 may share the same external airflow environment. For example, airflow supplied by the external cooling module may sequentially pass through multiple housings arranged within a rack or enclosure. Each housing may therefore receive cooling airflow from a shared airflow source while independently dissipating heat generated by its internal electronic components. Although the figure illustrates three housings 220, 230, and 240 for purposes of explanation, the system may include any suitable number of housings arranged in various configurations.

The airflow arrangement illustrated in FIG. 2A represents one example configuration and is not intended to be limiting. In other implementations, airflow paths may be arranged differently depending on system architecture, rack design, or cooling infrastructure. For example, airflow may be directed horizontally, vertically, or along other airflow paths, depending on the configuration of the external cooling module and the placement of the housings 220, 230, and 240.

FIG. 2B is a schematic diagram of an example computing device 250 and an air flow path associated with the example computing device 250. Note that the computing device 250 can be the same as, or similar to, the system 100 of FIG. 1A or system 160 of FIG. 1B. In some implementations, the computing device 250 can be a server including one or more trays of computing nodes.

As described above, the computing device 250 may include a housing 252 configured to enclose various electronic components. The housing 252 may define an air inlet 255 located at or near a front surface of the housing 252 and an air outlet 260 located at or near a back surface of the housing, which is the downstream of the airflow path. The air inlet 255 and the air outlet 260, together with internal structural arrangements within the housing 252, define an airflow path that allows cooling air supplied by an external cooling module to flow through the interior of the computing device 250. In operation, cooling air may enter the housing 252 through the air inlet 255, circulate through the interior of the housing 252 to remove heat generated by electronic components, and exit the housing through the air outlet 260.

The computing device 250 may enclose multiple electronic components arranged at different locations along the airflow path within the housing. As illustrated in FIG. 2B, the computing device 250 may include one or more memory units 270 (e.g., the memory units 115 of FIG. 1A), one or more GPUs 275 (e.g., the GPU 125 of FIG. 1A), one or more CPUs 280 (e.g., the CPUs 120-1 to 120-N of FIG. 1A), and/or other electronic components 285. The other electronic components 285 may include devices such as storage controllers, RAID cards (e.g., RAID card 135 of FIG. 1A), storage devices such as hard disk drives (e.g., hard disk drive 130 of FIG. 1A), graphics cards (e.g., graphics card 120 of FIG. 1A), network interface cards, power management circuitry, and/or other electronic devices mounted on the motherboard of the computing device 250. These electronic components may be arranged in groups at various locations within the housing and may generate heat during operation.

To dissipate heat generated by these electronic components, the computing device 250 may include a cooling module 295 configured to provide air cooling within the housing. In some implementations, the cooling module 295 may include multiple fans, such as Fan-1 (265-1), Fan-2 (265-2), . . . , and Fan-N (265-N) (referred to generally as fans 265 and individually as fan 265). These fans 265 may be positioned at various locations within the housing 252 along the airflow path. For example, one or more fans 265 may be positioned upstream or downstream of particular electronic components, or above or below those components, in order to promote airflow across the components and enhance heat dissipation. In some implementations, individual fans 265 may be associated with or assigned to one or more groups of electronic components based on their physical placement within the housing 252. For example, as illustrated in FIG. 2B, Fan-1 (265-1) may facilitate airflow for memory units 270, GPUs 275, and CPUs 280; Fan-2 (265-2) may facilitate airflow for GPUs 275, CPUs 280, and other electronic components 285; and Fan-N (265-N) may facilitate airflow for CPUs 280 and other electronic components 285. A control circuit (e.g., the control circuit 155 of FIG. 1A or the BMC 155 of FIG. 1B) of the computing device 250 may regulate the operation of one or more fans 265 to maintain appropriate temperature conditions for the corresponding groups of electronic components. For example, the computing device 250 may determine fan speeds based on the thermal requirements of multiple component groups associated with a given fan, e.g., selecting a fan speed that meets the maximum cooling requirement among the groups. The number of fans and the particular fan assignments are illustrated in FIG. 2B are provided for purposes of explanation and are not intended to be limiting.

The computing device 250 may further include one or more sensors 290-1, 290-2, 290-3, 290-4 (referred to generally as sensors 290 and individually as sensor 290) arranged within the housing 252. The sensors 290 can be the same as or similar to the sensors 145 of FIG. 1A or 1B The sensors 290 may include thermal sensors configured to measure localized temperatures associated with one or more electronic components. For example, as illustrated in FIG. 2B, sensors 290-1 may be associated with memory units 270, sensors 290-2 may be associated with GPUs 275, sensors 290-3 may be associated with CPUs 280, and sensors 290-4 may be associated with other electronic components 285. These sensors 290 may measure temperatures of the corresponding components or surrounding regions and may provide sensor data to the control circuit of the computing device 250, e.g., a BMC as described above. The control circuit may use the sensor data to determine operating parameters for the cooling module 295. As described above and shown in FIG. 2B, the computing device 250 does not include a thermal sensor positioned at or near the air outlet 260 for directly measuring outlet air temperature. Instead, the control circuit (e.g., BMC) is configured to estimate the temperature at the air outlet 260 based on information such as sensor measurements obtained within the housing 252, power consumption associated with electronic components, airflow characteristics such as the airflow volume at the air inlet or outlet, and/or other suitable information or data. Additional details regarding the algorithm for determining the outlet air temperature are described with further details with reference to FIG. 4.

FIG. 3 illustrates a first table 300 that represents a mapping between fan operating speeds and corresponding airflow volumes, and a second table 350 that represents candidate fan speeds for multiple fans associated with different groups of electronic components within a system. The system can be the same as, or similar to, the system 100 of FIG. 1A, the system 160 of FIG. 1B, the system 200 of FIG. 2A, or the computing device 250 of FIG. 2B.

Table 300 represents an example mapping between fan speed and airflow volume through a housing of the system. The airflow volume can be induced by operations of a particular fan installed in the system, more than one fans, or all fans installed therein. The airflow volume can be measured at the inlet of a housing of the system, or the outlet of the housing of the system. In some implementations, the airflow volume can be determined based on measurements at both the inlet and the outlet of the housing. In the illustrated example, the first column lists fan speeds expressed as percentages of a maximum configurable fan speed (e.g., ranging from 5% to 100%). The second column lists the corresponding airflow volume measured at the air inlet of the system, where airflow volume may be expressed in cubic feet per minute (CFM). Each row of Table 300 therefore represents a one-to-one correspondence between a particular fan speed of a particular fan (or all fans) included in the system and the resulting airflow volume at the inlet of the system.

In some implementations, the data represented in Table 300 may be obtained through calibration experiments. For example, a computing device or representative system configuration may be placed within a wind tunnel or other controlled airflow measurement environment. During the experiment, a controller may operate a particular fan at multiple predetermined speeds sequentially or in order while airflow volume at the air inlet or air outlet of the device is measured using airflow sensors or flow meters. These measurements may be repeated across a range of fan speeds to obtain empirical airflow data. Because airflow behavior may depend on structural characteristics of the computing device—such as the geometry of the housing, internal airflow channels, placement of electronic components, and locations of fans—the resulting fan-speed-to-airflow mapping may be specific to a particular system design. In some implementations, similar calibration experiments may be performed for multiple fans installed in the computing device so that airflow characteristics for each fan can be determined. For example, the controller may operate multiple or all fans installed in the system housing to rotate at the same speed for multiple predetermined speeds sequentially or in order, while airflow volume at the air inlet or outlet of the system is measured using airflow sensors or flow meters.

In some implementations, the discrete mapping values represented in Table 300 may be used to derive a continuous or analytical relationship between fan speed and airflow volume through a housing of the system. For example, interpolation, regression, or curve-fitting techniques may be applied to the experimental data to obtain an analytical expression that approximates the relationship between fan speed and airflow volume. Once such a relationship is established, the system may estimate airflow volume corresponding to a given fan speed, or alternatively, determine a fan speed required to achieve a desired airflow volume. The airflow volume determined using this relationship may be used in combination with other operating parameters—such as measured inlet temperature, estimated power consumption of electronic components, and other sensor data—to estimate the temperature at the air outlet of the system. Based on the estimated outlet temperature, the control circuit may determine updated operating parameters for one or more fans. Additional details regarding algorithms for determining outlet temperature and adjusting fan operation are described below with reference to FIG. 4.

Table 350 illustrates an example set of candidate fan speeds for multiple fans associated with different groups of electronic components within the system. In some implementations, the system may first estimate the temperature at the air outlet based on current fan speeds, power consumption of electronic components, and temperature measurements obtained near the air inlet of the system. The estimated outlet temperature may then be compared with a threshold or target temperature to determine candidate fan speeds for one or more fans (e.g., Fan-1, Fan-2, Fan-3, Fan-4, and Fan-5) in order to regulate thermal conditions at the air outlet of the system.

In addition to outlet-temperature considerations, candidate fan speeds may also be determined based on temperature measurements associated with particular groups of electronic components, such as CPUs, GPUs, and memory units. As illustrated in Table 350, each fan may have multiple candidate speed values derived from different thermal constraints associated with the components assigned to that fan. The system may then determine a final operating speed for each fan, e.g., by selecting one of the candidate fan speeds. In some implementations, the system may select the maximum candidate fan speed for each fan to ensure that the thermal requirements of all associated component groups are satisfied. For example, as illustrated in Table 350, Fan-1 may be set to 70% of its maximum configurable speed based on the highest candidate speed among its associated constraints. Similarly, Fan-2, Fan-3, Fan-4, and Fan-5 may be set to operating speeds of 70%, 70%, 70%, and 65% of their respective maximum configurable speeds. By selecting fan speeds in this manner, the system can coordinate the operation of multiple fans to maintain appropriate temperatures across different groups of electronic components while also regulating the estimated temperature at the air outlet.

FIG. 4 is a flow diagram of an example process 400 of managing a temperature at an air outlet (e.g., the air outlet 260 of FIG. 2B) of a system. The system can be, e.g., the system 100 of FIG. 1A, the system 160 of FIG. 1B, the system 200 of FIG. 2A, or the computing device 250 of FIG. 2B. For convenience, process 400 is described as being performed by a control circuit of the system. For example, the control circuit 155 (e.g., BMC) of FIGS. 1A and 1B, when appropriately programmed, can perform the process 400. For simplicity, the operations in process 400 are described below with respect to the control circuit in a system.

The control circuit is configured to receive data representing a first air temperature value at an air inlet (e.g., the air inlet of 155 of FIG. 2B) of a housing (e.g., the housing 220, 230 or 240 of FIG. 2A, or the housing 252 of FIG. 2B), a power consumption for the system, and a respective fan speed for each of the one or more fans (402). In some implementations, the control circuit may obtain data representing the power consumption for the system from a power supply unit (PSU) or a power monitoring circuit of the system. For example, the PSU may include a power monitoring interface configured to report real-time power consumption values, e.g., P in Watt (W), by electronic components in the system. In other implementations, power consumption information may be obtained from power telemetry provided by individual electronic components, such as processors (e.g., CPUs or GPUs) that report power usage through on-chip power monitoring circuitry or management interfaces. The power consumption can be 1 kW, 2 kW, 5 kW, 16 kW, 40 kW, 100 kW, or other suitable values depending on the design of the system and corresponding computation requirements.

The control circuit may further receive data representing the first air temperature value from a thermal sensor located at or near the air inlet. For example, the thermal sensor may be mounted near the front portion of the housing where cooling air enters the system, or near an intake region of the cooling airflow path. Measuring air temperature at the air inlet using a thermal sensor may provide a reliable representation of the temperature of the cooling air entering the system because the airflow at the air inlet is generally more uniform and less affected by internal thermal gradients. In contrast, air temperature near the air outlet may be influenced by localized heat sources, turbulent airflow patterns, and spatial temperature variations within the housing. As a result, a temperature sensor placed near the air outlet may measure only a localized temperature that may not accurately represent the bulk temperature of the air exiting the system. Accordingly, the described techniques estimate the air outlet temperature using inlet temperature measurements in combination with other operating parameters, rather than relying on direct outlet temperature measurements by a thermal sensor located near or at the air outlet.

The control circuit is configured to determine an airflow volume through the housing based on the respective one or more fan speeds for the one or more fans (404). The airflow volume can be measured at an air inlet or an air outlet of the housing. In some implementations, the airflow volume can be determined based on measurements at both air inlet and outlet of the housing. As described above, the air outlet is positioned downstream of the air inlet along an airflow path extending through the housing of the system. In some implementations, the control circuit may determine the airflow contribution associated with each fan based on the respective fan speed of that fan and a corresponding relationship between fan speed and airflow volume.

As described above, for each fan, the control circuit may reference a mapping between configurable fan speeds and corresponding airflow volumes, e.g., as illustrated in Table 300 of FIG. 3A. Such a mapping may represent a one-to-one correspondence between fan speed values (e.g., expressed as percentages of maximum configurable speed or rotational speeds in revolutions per minute (RPM)) and airflow volumes generated by the fan through the housing (e.g., expressed in cubic feet per minute (CFM)). Based on the current operating speed of a fan, the control circuit may determine the airflow volume contributed by that fan that travels through the system. As described above, the one-to-one mapping can also be determined for fan speeds operated by all fans in the system and the corresponding airflow volumes through the system.

In some implementations, the mapping between fan speed and airflow volume may be obtained through calibration testing. For example, as discussed above with respect to FIG. 3A, during a calibration procedure, a representative computing device or system configuration may be placed within a wind tunnel or other controlled airflow measurement environment. The fan may be operated at multiple configurable speed levels, and the resulting airflow volume through the housing may be measured using airflow sensors or flow meters positioned at the air outlet. By repeating these measurements across a range of fan speeds, a set of empirical data points relating fan speed to airflow volume may be obtained. The control circuit may then generate a mapping function or lookup table by interpolating the measured airflow data corresponding to the configurable fan speeds. Using this mapping, the control circuit may determine the airflow volume associated with a given fan speed during system operation.

In implementations including multiple fans, the control circuit may determine an overall airflow volume through the system by combining the airflow contributions associated with the individual fans, such as by summing or otherwise aggregating the airflow volumes corresponding to the respective fan speeds. In some implementations, the control circuit may determine the overall airflow volume through the system by measuring data at the system's air inlet and/or outlet. Based on the determined overall airflow volume, the control circuit may further determine the respective portion of the overall airflow volume contributed by each individual fan installed in the system. For example, assuming all fans in the system operate at the same speed, the control circuit can determine the portion of the overall airflow by dividing the overall airflow by the number of fans installed.

The control circuit is configured to determine a second air temperature value at the air outlet based on the first air temperature value at the air inlet, the power consumption, and the airflow volume (406). To determine the second air temperature, the control circuit may determine a temperature difference between the second air temperature value at the air outlet and the first air temperature value at the air inlet. Based on the temperature difference and the first air temperature value at the air inlet, the control circuit may determine the second air temperature value at the air outlet. For example, the second air temperature may be calculated by summing the first air temperature and the temperature difference. In some implementations, the control circuit may determine the temperature difference according to the expression below:

$$Δ T = k \times P / V , \qquad Expression ( 1 )$$

where ΔT represents the temperature difference, k represents a predetermined coefficient, P represents the power consumption, and V represents the airflow volume. Note that for the temperature represented using Celsius, the predetermined coefficient k has a value of 1.76, and for temperature values represented using Fahrenheit, the predetermined coefficient k has a value of 3.1. Those values are approximate for industry and engineering purposes, but other values substantially similar may also be applicable for the described techniques.

Note again that, as described above, the control circuit determines the second air temperature value at the air outlet without relying on data sensed by a thermal sensor located in the vicinity of the air outlet, since temperature values measured at the air outlet using a thermal sensor may be inaccurate for control purposes, as described above.

The control circuit is configured to determine whether the second air temperature value satisfies a threshold temperature value (408). In some implementations, a temperature value does not satisfy the threshold if it exceeds the threshold. In some other implementations, a temperature value does not satisfy the threshold if it exceeds an acceptable range, including the threshold temperature value. If the temperature value satisfies the threshold temperature value or stays within an acceptable range, the control circuit may maintain the fan speed for controlling the temperature at the air outlet. The threshold temperature value can be 10, 20, 40, 60 Celsius degrees, or other suitable temperature values.

However, in response to determining that the second air temperature value fails to satisfy the threshold temperature value, the control circuit may update at least one of the one or more respective fan speeds for the one or more fans accordingly (410). For example, if the determined air outlet temperature exceeds a target or threshold temperature or a range, the control circuit may increase the speed of one or more fans to increase airflow through the housing and thereby enhance heat removal from the electronic components. Conversely, if the determined air outlet temperature is below the threshold temperature, the control circuit may reduce the speed of one or more fans to reduce unnecessary cooling effort and associated power consumption. In some implementations, the control circuit may determine updated fan speeds based on the estimated airflow volume required to maintain the outlet temperature within a desired operating range. The updated fan speeds may then be transmitted to the corresponding fans through control signals, such as pulse width modulation (PWM) control signals or target rotational speed commands.

In some implementations, the control circuit may determine updated fan speeds for the fans through a multi-constraint selection process. For example, for each of the one or more fans, the control circuit may determine a first candidate fan speed based on the second air temperature value at the air outlet. This candidate fan speed may correspond to an airflow volume required to bring the outlet air temperature within the threshold temperature range. In addition, the control circuit may determine one or more additional candidate fan speeds for the same fan based on sensor data associated with electronic components located within the housing, such as temperatures measured for CPUs, GPUs, memory units, or other electronic components. The control circuit may then select, as the updated fan speed for the fan, a fan speed from among the candidate fan speeds determined from these different constraints. In some implementations, the control circuit may select the maximum candidate fan speed to ensure that all thermal requirements associated with the outlet airflow temperature and the electronic components are satisfied.

After the updated fan speeds for the one or more fans are determined, the control circuit may update the airflow volume estimation for the system. For example, the control circuit may determine an updated airflow volume through the housing based on the updated fan speeds and the fan-speed-to-airflow mappings described above. Using the updated airflow volume, the control circuit may then determine an updated second air temperature value at the air outlet. The control circuit may iteratively perform these determinations until the estimated outlet temperature satisfies the threshold temperature value or falls within a desired temperature range containing the threshold temperature value, e.g., as shown in FIG. 4.

FIG. 5 is a block diagram illustrating an example architecture of a computing device 500 used to provide computational functionalities associated with described algorithms, methods, functions, processes, flows, and procedures. Other architectures are possible, including architectures with more or fewer components. The computing device can be implemented as the system 100 of FIG. 1A, the system 160 of FIG. 1B, or the computing device 250 of FIG. 2B. The computing device 500 includes processor 504, memory 506, storage component 508, input interface 510, output interface 512, communication interface 514, and bus 502.

Bus 502 includes a component that permits communication among the components of the computing device 500. In some embodiments, processor 504 is implemented in hardware, software, or a combination of hardware and software. In some examples, processor 504 includes a processor (e.g., a central processing unit (CPU), a graphics processing unit (GPU), an accelerated processing unit (APU), and/or the like), a microphone, a digital signal processor (DSP), and/or any processing component (e.g., a field-programmable gate array (FPGA), an application specific integrated circuit (ASIC), and/or the like) that can be programmed to perform at least one function. Memory 506 includes random access memory (RAM), read-only memory (ROM), and/or another type of dynamic and/or static storage device (e.g., flash memory, magnetic memory, optical memory, and/or the like) that stores data and/or instructions for use by processor 504.

Storage component 508 stores data and/or software related to the operation and use of the computing device 500. In some examples, storage component 508 includes a hard disk (e.g., a magnetic disk, an optical disk, a magneto-optic disk, a solid state disk, and/or the like), a compact disc (CD), a digital versatile disc (DVD), a floppy disk, a cartridge, a magnetic tape, a CD-ROM, RAM, PROM, EPROM, FLASH-EPROM, NV-RAM, and/or another type of computer readable medium, along with a corresponding drive.

Input interface 510 includes a component that permits the computing device 500 to receive information, such as via user input (e.g., a touchscreen display, a keyboard, a keypad, a mouse, a button, a switch, a microphone, a camera, and/or the like). Additionally or alternatively, in some embodiments, input interface 510 includes a sensor that senses information (e.g., a global positioning system (GPS) receiver, an accelerometer, a gyroscope, an actuator, and/or the like). Output interface 512 includes a component that provides output information from the computing device 500 (e.g., a display, a speaker, one or more light-emitting diodes (LEDs), and/or the like).

In some embodiments, communication interface 514 includes a transceiver-like component (e.g., a transceiver, a separate receiver and transmitter, and/or the like) that permits the computing device 500 to communicate with other devices via a wired connection, a wireless connection, or a combination of wired and wireless connections. In some examples, communication interface 514 permits the computing device 500 to receive information from another device and/or provide information to another device. In some examples, communication interface 514 includes an Ethernet interface, an optical interface, a coaxial interface, an infrared interface, a radio frequency (RF) interface, a universal serial bus (USB) interface, a Wi-Fi® interface, a cellular network interface, and/or the like.

In some embodiments, the computing device 500 performs one or more processes described herein. The computing device 500 performs these processes based on processor 504 executing software instructions stored by a computer-readable medium, such as memory 506 and/or storage component 508. A computer-readable medium (e.g., a non-transitory computer-readable medium) is defined herein as a non-transitory memory device. A non-transitory memory device includes memory space located inside a single physical storage device or memory space spread across multiple physical storage devices.

In some embodiments, software instructions are read into memory 506 and/or storage component 508 from another computer-readable medium or another device via communication interface 514. When executed, software instructions stored in memory 506 and/or storage component 508 cause processor 504 to perform one or more processes described herein. Additionally or alternatively, hardwired circuitry is used in place of or in combination with software instructions to perform one or more processes described herein. Thus, embodiments described herein are not limited to any specific combination of hardware circuitry and software unless explicitly stated otherwise.

Memory 506 and/or storage component 508 includes data storage or at least one data structure (e.g., a database and/or the like). The computing device 500 is capable of receiving information from, storing information in, communicating information to, or searching information stored in the data storage or at least one data structure in memory 506 or storage component 508. In some examples, the information includes network data, input data, output data, or any combination thereof.

In some embodiments, the computing device 500 is configured to execute software instructions that are either stored in memory 506 and/or in the memory of another device (e.g., another device that is the same as or similar to the computing device 500). As used herein, the term “module” refers to at least one instruction stored in memory 506 and/or in the memory of another device that, when executed by processor 504 and/or by a processor of another device (e.g., another device that is the same as or similar to the computing device 500) cause the computing device 500 (e.g., at least one component of the computing device 500) to perform one or more processes described herein. In some embodiments, a module is implemented in software, firmware, hardware, and/or the like.

The number and arrangement of components illustrated in FIG. 5 are provided as an example. In some embodiments, the computing device 500 can include additional components, fewer components, different components, or differently arranged components than those illustrated in FIG. 5. Additionally or alternatively, a set of components (e.g., one or more components) of the computing device 500 can perform one or more functions described as being performed by another component or another set of components of the computing device 500.

FIG. 6 illustrates an example architecture 600 of a computing system used to provide computational functionalities associated with described algorithms, methods, functions, processes, flows, and procedures. The computing system can include one or more computing devices, such as the system 100 of FIG. 1A, the system 160 of FIG. 1B or the system 200 of FIG. 2A. Other architectures are possible, including architectures with more or fewer components.

In some implementations, architecture 600 includes one or more processor(s) 602 (e.g., dual-core Intel® Xeon® Processors), one or more network interface(s) 606, one or more storage device(s) 604 (e.g., hard disk, optical disk, flash memory), and one or more computer-readable medium(s) 608 (e.g., hard disk, optical disk, flash memory, etc.). These components can exchange communications and data over one or more communication channel(s) 610 (e.g., buses), which can utilize various hardware and software for facilitating the transfer of data and control signals between components.

The term “computer-readable medium” refers to any medium that participates in providing instructions to the processor(s) 602 for execution, including, without limitation, non-volatile media (e.g., optical or magnetic disks), volatile media (e.g., memory), and transmission media. Transmission media includes, without limitation, coaxial cables, copper wire, and fiber optics.

Computer-readable medium(s) 608 can further include instructions 612 for an operating system (e.g., Mac OS® server, Windows® NT server, Linux Server), instructions 614 for network communications module, data processing instructions 616, and interface instructions 618.

Operating systems can be multi-user, multiprocessing, multitasking, multithreading, real time, etc. Operating system performs basic tasks, including but not limited to: recognizing input from and providing output to devices 602, 604, 606 and 608; keeping track and managing files and directories on computer-readable medium(s) 608 (e.g., memory or a storage device); controlling peripheral devices; and managing traffic on the one or more communication channel(s) 610. Network communications module includes various components for establishing and maintaining network connections (e.g., software for implementing communication protocols, such as TCP/IP, HTTP, etc.) and for creating a distributed streaming platform using, for example, Apache Kafka™. Data processing instructions 616 include server-side or backend software for implementing the server-side operations. Interface instructions 618 includes software for implementing a web server and/or portal for sending and receiving data to and from user side computing devices and service provider side computing devices.

Architecture 600 can be implemented by a cloud computing system and can be included in any computer device, including one or more server computers in a local or distributed network each having one or more processing cores. Architecture 600 can be implemented in a parallel processing or peer-to-peer infrastructure or on a single device with one or more processors. Software can include multiple software components or can be a single body of code.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs, that is, one or more modules of computer program instructions encoded on a tangible, non-transitory, computer-readable medium for execution by, or to control the operation of, a computer or computer-implemented system. Alternatively, or additionally, the program instructions can be encoded in/on an artificially generated propagated signal, for example, a machine-generated electrical, optical, or electromagnetic signal that is generated to encode information for transmission to a receiver apparatus for execution by a computer or computer-implemented system. The computer-storage medium can be a machine-readable storage device, a machine-readable storage substrate, a random or serial access memory device, or a combination of computer-storage mediums. Configuring one or more computers means that the one or more computers have installed hardware, firmware, or software (or combinations of hardware, firmware, and software) so that when the software is executed by the one or more computers, particular computing operations are performed. The computer storage medium is not, however, a propagated signal.

The term “real-time,” “real time,” “realtime,” “real (fast) time (RFT),” “near(ly) real-time (NRT),” “quasi real-time,” or similar terms (as understood by one of ordinary skill in the art), means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

The terms “data processing apparatus,” “computer,” “computing device,” or “electronic computer device” (or an equivalent term as understood by one of ordinary skill in the art) refer to data processing hardware and encompass all kinds of apparatuses, devices, and machines for processing data, including by way of example, a programmable processor, a computer, or multiple processors or computers. The computer can also be, or further include special-purpose logic circuitry, for example, a central processing unit (CPU), a field-programmable gate array (FPGA), or an application-specific integrated circuit (ASIC). In some implementations, the computer or computer-implemented system or special-purpose logic circuitry (or a combination of the computer or computer-implemented system and special-purpose logic circuitry) can be hardware- or software-based (or a combination of both hardware- and software-based). The computer can optionally include code that creates an execution environment for computer programs, for example, code that constitutes processor firmware, a protocol stack, a database management system, an operating system, or a combination of execution environments. The present disclosure contemplates the use of a computer or computer-implemented system with an operating system, for example LINUX, UNIX, WINDOWS, MAC OS, ANDROID, or IOS, or a combination of operating systems.

A computer program, which can also be referred to or described as a program, software, a software application, a unit, a module, a software module, a script, code, or other component can be written in any form of programming language, including compiled or interpreted languages, or declarative or procedural languages, and it can be deployed in any form, including, for example, as a stand-alone program, module, component, or subroutine, for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files, for example, files that store one or more modules, sub-programs, or portions of code. A computer program can be deployed to be executed on one computer or on multiple computers that are located at one site or distributed across multiple sites and interconnected by a communication network.

While portions of the programs illustrated in the various figures can be illustrated as individual components, such as units or modules, that implement described features and functionality using various objects, methods, or other processes, the programs can instead include a number of sub-units, sub-modules, third-party services, components, libraries, and other components, as appropriate. Conversely, the features and functionality of various components can be combined into single components, as appropriate. Thresholds used to make computational determinations can be statically, dynamically, or both statically and dynamically determined.

Described methods, processes, or logic flows represent one or more examples of functionality consistent with the present disclosure and are not intended to limit the disclosure to the described or illustrated implementations, but to be accorded the widest scope consistent with described principles and features. The described methods, processes, or logic flows can be performed by one or more programmable computers executing one or more computer programs to perform functions by operating on input data and generating output data. The methods, processes, or logic flows can also be performed by, and computers can also be implemented as, special-purpose logic circuitry, for example, a CPU, an FPGA, or an ASIC.

Computers for the execution of a computer program can be based on general or special-purpose microprocessors, both, or another type of CPU. Generally, a CPU will receive instructions and data from and write to a memory. The essential elements of a computer are a CPU, for performing or executing instructions, and one or more memory devices for storing instructions and data. Generally, a computer will also include, or be operatively coupled to, receive data from or transfer data to, or both, one or more mass storage devices for storing data, for example, magnetic, magneto-optical disks, or optical disks. However, a computer need not have such devices. Moreover, a computer can be embedded in another device, for example, a mobile telephone, a personal digital assistant (PDA), a mobile audio or video player, a game console, a global positioning system (GPS) receiver, or a portable memory storage device, for example, a universal serial bus (USB) flash drive, to name just a few.

Non-transitory computer-readable media for storing computer program instructions and data can include all forms of permanent/non-permanent or volatile/non-volatile memory, media and memory devices, including by way of example semiconductor memory devices, for example, random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices; magnetic devices, for example, tape, cartridges, cassettes, internal/removable disks; magneto-optical disks; and optical memory devices, for example, digital versatile/video disc (DVD), compact disc (CD)-ROM, DVD+/−R, DVD-RAM, DVD-ROM, high-definition/density (HD)-DVD, and BLU-RAY/BLU-RAY DISC (BD), and other optical memory technologies. The memory can store various objects or data, including caches, classes, frameworks, applications, modules, backup data, jobs, web pages, web page templates, data structures, database tables, repositories storing dynamic information, or other appropriate information including any parameters, variables, algorithms, instructions, rules, constraints, or references. Additionally, the memory can include other appropriate data, such as logs, policies, security or access data, or reporting files. The processor and the memory can be supplemented by, or incorporated in, special-purpose logic circuitry.

To provide for interaction with a user, implementations of the subject matter described in this specification can be implemented on a computer having a display device, for example, a cathode ray tube (CRT), liquid crystal display (LCD), light emitting diode (LED), or plasma monitor, for displaying information to the user and a keyboard and a pointing device, for example, a mouse, trackball, or trackpad by which the user can provide input to the computer. Input can also be provided to the computer using a touchscreen, such as a tablet computer surface with pressure sensitivity or a multi-touch screen using capacitive or electric sensing. Other types of devices can be used to interact with the user. For example, feedback provided to the user can be any form of sensory feedback (such as, visual, auditory, tactile, or a combination of feedback types). Input from the user can be received in any form, including acoustic, speech, or tactile input. In addition, a computer can interact with the user by sending documents to and receiving documents from a client computing device that is used by the user (for example, by sending web pages to a web browser on a user's mobile computing device in response to requests received from the web browser).

The term “graphical user interface (GUI) can be used in the singular or the plural to describe one or more graphical user interfaces and each of the displays of a particular graphical user interface. Therefore, a GUI can represent any graphical user interface, including but not limited to, a web browser, a touch screen, or a command line interface (CLI) that processes information and efficiently presents the information results to the user. In general, a GUI can include a number of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server, or that includes a front-end component, for example, a client computer having a graphical user interface or a Web browser through which a user can interact with an implementation of the subject matter described in this specification, or any combination of one or more such back-end, middleware, or front-end components. The components of the system can be interconnected by any form or medium of wireline or wireless digital data communication (or a combination of data communication), for example, a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) using, for example, 802.11x or other protocols, all or a portion of the Internet, another communication network, or a combination of communication networks. The communication network can communicate with, for example, Internet Protocol (IP) packets, frame relay frames, Asynchronous Transfer Mode (ATM) cells, voice, video, data, or other information between network nodes.

The computing system can include clients and servers. A client and server are generally remote from each other and typically interact through a communication network. The relationship of client and server arises by virtue of computer programs running on the respective computers and having a client-server relationship to each other.

The separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the scope of the present disclosure.

Furthermore, any claimed implementation is considered to be applicable to at least a computer-implemented method; a non-transitory, computer-readable medium storing computer-readable instructions to perform the computer-implemented method; and a computer system including a computer memory interoperably coupled with a hardware processor configured to perform the computer-implemented method or the instructions stored on the non-transitory, computer-readable medium.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances.

As used herein, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or, A and B.” As used herein, the term “and/or” as used herein refers to and encompasses any and all possible combinations of one or more of the associated listed terms. For example, the term “A and/or B” means that either option A, option B, or both options A and B are possible, where A and B may be singular or plural.

As used herein, the term “about” or “approximately” can allow for a degree of variability in a value or range, for example, within 10%, within 5%, or within 1% of a stated value or of a stated limit of a range. As used herein, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

In addition, the phraseology or terminology employed in the present disclosure, and not otherwise defined, is for the purpose of description only and not of limitation. Any use of section headings is intended to aid reading of the document and is not to be interpreted as limiting; information that is relevant to a section heading may occur within or outside of that particular section.

While this specification contains many specific implementation details, these should not be construed as limitations on the scope of any inventive concept or on the scope of what can be claimed, but rather as descriptions of features that can be specific to particular implementations of particular inventive concepts. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations can be considered optional), to achieve desirable results. In certain circumstances, multitasking or parallel processing (or a combination of multitasking and parallel processing) can be advantageous and performed as deemed appropriate.

The breadth and scope of the present disclosure should not be limited by any of the above-described exemplary implementations, but should be defined only in accordance with the following claims and their equivalents.

What is claimed is:

1. A system, comprising:
a housing;
a plurality of electronic components;
a control circuit; and
one or more fans,
wherein the housing encloses the plurality of electronic components, the control circuit, and the one or more fans, and
wherein the control circuit is configured to:
receive data representing a first air temperature value at an air inlet of the housing, a power consumption for the system, and a respective fan speed for each of the one or more fans;
determine an airflow volume through the housing based on respective one or more fan speeds for the one or more fans; and
determine a second air temperature value at an air outlet based on the first air temperature value at the air inlet, the power consumption, and the airflow volume, the air outlet being downstream of the air inlet along an air flow path through the housing.

2. The system of claim 1, wherein the control circuit is configured to:
for each of the one or more fans, determine the airflow volume through the housing based on the respective fan speed for the fan and a one-to-one mapping between fan speeds configurable for the fan and corresponding airflow volumes for the fan.

3. The system of claim 2, wherein the one-to-one mapping is determined for each of the one or more fans by operations comprising:
for each of the fan speeds configurable for the fan, measuring an airflow volume through the housing generated by the fan in a wind tunnel; and
determining the one-to-one mapping for the fan by interpolating the fan speeds configurable for the fan and the measured airflow volumes for the fan speeds.

4. The system of claim 1, wherein the control circuit is configured to:
determine a temperature difference between the second air temperature value at the air outlet and the first air temperature value at the air inlet; and
determine the second air temperature value at the air outlet based on the temperature difference and the first air temperature value at the air inlet.

5. The system of claim 4, wherein the temperature difference is determined according to an expression as below:
$$Δ T = k \times P / V ,$$
where ΔT represents the temperature difference, k represents a predetermined coefficient, P represents the power consumption, and V represents the airflow volume.

6. The system of claim 1, wherein the control circuit is configured to:
determine whether the second air temperature value satisfies a threshold temperature value; and
update at least one of the one or more respective fan speeds for the one or more fans in response to determining that the second air temperature value fails to satisfy the threshold temperature value.

7. The system of claim 6, wherein the control circuit is configured to:
for each of the one or more fans,
determine a candidate fan speed for the fan based on the second air temperature value at the air outlet; and
select, as an updated fan speed for the fan, a fan speed from (i) the candidate fan speed and (ii) additional fan speeds for the fan based on sensor data associated with one or more electronic components of the plurality of electronic components in the system.

8. The system of claim 7, wherein the control circuit is configured to:
receive one or more updated fan speeds for the one or more fans;
determine an updated airflow volume through the housing based on the one or more updated fan speeds for the one or more fans; and
determine an updated second air temperature value at the air outlet based on the updated airflow volume.

9. The system of claim 1, wherein the control circuit is configured to determine the second air temperature value at the air outlet without relying on data sensed by a thermal sensor located in a vicinity of the air outlet.

10. The system of claim 1, wherein the control circuit is configured to receive data representing the power consumption for the system from a power supply unit of the system.

11. The system of claim 1, wherein the control circuit is configured to receive data representing the first air temperature value at the air inlet of the housing from a thermal sensor located in a vicinity of the air inlet.

12. The system of claim 1, wherein the control circuit comprises a Baseboard Management Controller (BMC).

13. A method performed by a control circuit of a system, comprising a housing that contains a plurality of electronic components, the control circuit, and one or more fans, wherein the method comprises:
receiving data representing a first air temperature value at an air inlet of the housing, a power consumption for the system, and a respective fan speed for each of the one or more fans;
determining an airflow volume through the housing based on respective one or more fan speeds for the one or more fans; and
determine a second air temperature value at an air outlet based on the first air temperature value at the air inlet, the power consumption, and the airflow volume, the air outlet being downstream the air inlet along an air flow path through the housing.

14. The method of claim 13, further comprising:
determining, for each of the one or more fans, the airflow volume through the housing based on the respective fan speed for the fan and a one-to-one mapping between fan speeds configurable for the fan and corresponding airflow volumes for the fan.

15. The method of claim 14, wherein the one-to-one mapping is determined for each of the one or more fans by operations comprising:
for each of the fan speeds configurable for the fan, measuring an airflow volume through the housing generated by the fan in a wind tunnel; and
determining the one-to-one mapping for the fan by interpolating the fan speeds configurable for the fan and the measured airflow volumes for the fan speeds.

16. The method of claim 13, further comprising:
determining a temperature difference between the second air temperature value at the air outlet and the first air temperature value at the air inlet; and
determining the second air temperature value at the air outlet based on the temperature difference and the first air temperature value at the air inlet.

17. The method of claim 16, wherein the temperature difference is determined according to an expression as below:
$$Δ T = k \times P / V ,$$
where ΔT represents the temperature difference, k represents a predetermined coefficient, P represents the power consumption, and V represents the airflow volume.

18. The method of claim 13, further comprising:
determining whether the second air temperature value satisfies a threshold temperature value; and
updating at least one of the one or more respective fan speeds for the one or more fans in response to determining that the second air temperature value fails to satisfy the threshold temperature value.

19. The method of claim 16, further comprising:
for each of the one or more fans,
determining a candidate fan speed for the fan based on the second air temperature value at the air outlet; and
selecting, as an updated fan speed for the fan, a fan speed from (i) the candidate fan speed and (ii) additional fan speeds for the fan based on sensor data associated with one or more electronic components of the plurality of electronic components in the system.

20. An apparatus, comprising:
at least one processor; and
one or more non-transitory computer-readable media storing instructions executable by the at least one processor to perform operations comprising:
receiving data representing a first air temperature value at an air inlet of a housing of a system, a power consumption for the system, and a respective fan speed for each of one or more fans of the system, wherein the housing encloses a plurality of electronic components of the system and the one or more fans;
determining an airflow volume through the housing based on respective one or more fan speeds for the one or more fans; and
determining a second air temperature value at an air outlet based on the first air temperature value at the air inlet, the power consumption, and the airflow volume, the air outlet being downstream the air inlet along an air flow path through the housing.
